(19) United States
(12) Patent Application Publication
(10) Pub. No.: US 2023/0332291 A1
(43) Pub. Date: Oct. 19, 2023

(54) REMOTE PLASMA ARCHITECTURE FOR TRUE RADICAL PROCESSING

(71) Applicant: Lam Research Corporation, Fremont, CA (US)

(72) Inventors: Bhadri VARADARAJAN, Beaverton, OR (US); Aaron DURBIN, Portland, OR (US); Huatan QIU, Portland, OR (US); Bo GONG, Sherwood, OR (US); Rachel E. BATZER, Tigard, OR (US); Gopinath BHIMARASETTI, Portland, OR (US); Aaron Blake MILLER, West Linn, OR (US); Patrick G. BREILING, Tigard, OR (US); Geoffrey HOHN, Portland, OR (US)

(21) Appl. No.: 18/245,623

(22) PCT Filed: Sep. 21, 2021
(86) PCT No.: PCT/US2021/051179

§ 371 Date: Mar. 16, 2023

Related U.S. Application Data
(60) Provisional application No. 63/084,541, filed on Sep. 28, 2020.

(51) Int. Cl. C23C 16/455; H01J 37/32

(52) U.S. Cl. CPC C23C 16/45565; H01J 37/3244; H01J 37/32357

(57) ABSTRACT

A showerhead comprises first, second, and third components. The first component includes a disc-shaped portion and a cylindrical portion extending perpendicularly from the disc-shaped portion. The disc-shaped portion includes first and second sets of holes having first and second diameters, respectively, that extend from a center of the disc-shaped portion to an inner diameter of the cylindrical portion. The second component is disc-shaped and is attached to the disc-shaped portion of the first component, defines a plenum that is in fluid communication with the second set of holes, and includes a pair of arc-shaped grooves along a periphery and on opposite ends of the top surface and a plurality of grooves extending between the pair of arc-shaped grooves. The third component is disc-shaped, is attached to the second component, and includes a gas inlet connected to the plenum, and fluid inlet and outlet connected to the arc-shaped grooves.

### CROSS-REFERENCE TO RELATED APPLICATIONS

This application claims the benefit of U.S. Provisional Application No. 63/084,541, filed on Sep. 28, 2020. The entire disclosure of the application referenced above is incorporated herein by reference.

### FIELD

The present disclosure relates generally to substrate processing systems and more particularly to a remote plasma architecture for true radical processing.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems typically include a processing chamber enclosing a pedestal on which a substrate such as a semiconductor wafer is arranged during processing. A gas delivery system may introduce a process gas mixture including one or more precursors into the processing chamber to deposit a film on the substrate or to etch the substrate. Plasma may be struck in the processing chamber. Alternatively, plasma may be generated remotely from (i.e., outside) the processing chamber and then introduced into the processing chamber. Plasma generated outside the processing chamber is called remote plasma and may be generated using any method including capacitively coupled plasma (CCP), inductively coupled plasma (ICP), transformed coupled plasma (TCP), and microwave.

Some substrate processing systems use an atomic layer deposition (ALD) process to deposit material on substrates. ALD is a thin-film deposition method that sequentially performs a gaseous chemical process to deposit a thin film on a surface of a substrate. ALD uses at least two chemicals called precursors (reactants) that react with the surface of the substrate one precursor at a time in a sequential, self-limiting manner. Through repeated exposure to separate precursors, a thin film is gradually deposited on the surface of the substrate.

### SUMMARY

A showerhead for processing a substrate in a processing chamber comprises a first component, a second component, and a third component. The first component includes a disc-shaped portion and a cylindrical portion extending perpendicularly from the disc-shaped portion. The disc-shaped portion has a greater diameter than an outer diameter of the cylindrical portion. The cylindrical portion has an inner diameter greater than a diameter of the substrate. The disc-shaped portion includes first and second sets of holes having first and second diameters, respectively. The first and second sets of holes extend from a center of the disc-shaped portion to the inner diameter of the cylindrical portion. The second component is disc-shaped and includes first through holes aligned with the first set of holes in the first component. The second component has a top surface, side surfaces, and a bottom surface attached to the disc-shaped portion of the first component on a side opposite to the cylindrical portion and defining a plenum. The plenum is in fluid communication with the second set of holes in the first component and is separate from the first set of holes in the first component. The top surface of the second component includes a pair of arc-shaped grooves along a periphery and on opposite ends of the top surface and includes a plurality of grooves extending between the pair of arc-shaped grooves. The third component is disc-shaped and includes second through holes aligned with the first through holes in the second component and with the first set of holes in the first component. The third component has a bottom surface attached to the top surface of the second component.

In another feature, the first and second sets of holes are arranged in a hexagonal pattern.

In another feature, the first and second sets of holes are arranged in a triangular pattern.

In another feature, the first and second sets of holes are arranged using a combination of a hexagonal pattern and a triangular pattern.

In other features, hexagons in the hexagonal pattern are equilateral hexagons, and triangles in the triangular pattern are equilateral triangles.

In other features, the first set of holes are arranged in a hexagonal pattern, the second set of holes are lie on vertices of triangles within hexagons formed by the first set of holes, and one of the first set of holes lies within each of the triangles.

In other features, the second set of holes are arranged in a hexagonal pattern, the first set of holes are lie on vertices of triangles within hexagons formed by the second set of holes, and one of the second set of holes lies within each of the triangles.

In other features, the third component further comprises a gas inlet in fluid communication with the plenum, a fluid inlet in fluid communication with a first one of the pair of arc-shaped grooves, and a fluid outlet in fluid communication with a second one of the pair of arc-shaped grooves.

In another feature, the pair of arc-shaped grooves and the plurality of grooves are separate from the plenum and the first and second sets of holes.

In another feature, the bottom surface of the second component further comprises a semicircular groove along a periphery of the bottom surface of the second component, and the semicircular groove is in fluid communication with the plenum.

In another feature, the semicircular groove surrounds the first through holes in the second component.

In another feature, the semicircular groove surrounds the pair of arc-shaped grooves.

In another feature, the pair of arc-shaped grooves include a plurality of vertically extending ridges that contact the bottom surface of the third component.

In another feature, a height of the ridges is equal to a depth of the plurality of grooves.

In another feature, the pair of arc-shaped grooves surround the first through holes in the second component.

In another feature, the pair of arc-shaped grooves and the plurality of grooves have equal depths.

In another feature, the plurality of grooves are parallel to each other.

In another feature, the plurality of grooves have a zig-zagged shape.

In another feature, first ends of the plurality of grooves connect with a first one of the pair of arc-shaped grooves, and second ends of the plurality of grooves connect with a second one of the pair of arc-shaped grooves.

In another feature, the first through holes in the second component lie between the plurality of grooves.

In other features, the third component comprises an annular ridge on a top surface of the third component along a periphery of the third component, and a recess extending from an inner diameter of the annular ridge to a center of the top surface of the third component.

In another feature, the inner diameter of the annular ridge is greater than or equal to the inner diameter of the cylindrical portion of the first component.

In another feature, an outer diameter of the annular ridge is greater than or equal to an outer diameter of the cylindrical portion of the first component.

In another feature, a width of the annular ridge is greater than or equal to a thickness of the cylindrical portion of the first component.

In another feature, the inner diameter of the annular ridge is greater than the diameter of the substrate.

In another feature, a diameter of the recess is greater than or equal to the inner diameter of the cylindrical portion of the first component.

In another feature, the recess has a greater diameter than the diameter of the substrate.

In another feature, the second through holes in the third component lie within the inner diameter of the annular ridge.

In another feature, the second through holes in the third component lie within the recess.

In another feature, the first, second, and third components are diffusion bonded.

In another feature, a ratio of a sum of cross-sectional area of the first set of holes to a cross-sectional area of the cylindrical portion of the first component is between 4.5% and 5.5%.

In another feature, a ratio of a sum of cross-sectional area of the first set of holes to a cross-sectional area of the cylindrical portion of the first component is between 4% and 6%.

In another feature, a ratio of a number of the first set of holes to a number of second set of holes is between 1.00 and 1.05.

In another feature, a density of the first and second sets of holes is between 4 and 5 holes per square inch.

In other features, a system comprises the showerhead, the processing chamber, and a plasma generator arranged above the third component of the showerhead to supply plasma to the showerhead. The showerhead is arranged at a top end of the processing chamber. The system comprises a pedestal arranged in the processing chamber. The cylindrical portion of the first component of the showerhead surrounds a top portion of the pedestal. The system comprises a gas delivery system to supply a gas to the plenum, and a fluid delivery system to supply a fluid to one of the pair of arc-shaped grooves.

In another feature, the first set of holes in the showerhead filter ions from the plasma and pass radicals from the plasma through the showerhead into the processing chamber.

In another feature, a film deposited on the substrate has a non-uniformity of 0.0%.

In another feature, a film deposited on the substrate has a non-uniformity of less than 0.1%.

In another feature, a gap between a bottom surface of the disc-shaped portion of the first component of the showerhead and a top surface of the pedestal is between 0.11 in. and 0.2 in.

In another feature, the processing chamber includes an atomic layer deposition (ALD) processing chamber, an atomic layer etch (ALE) processing chamber, a chemical vapor deposition (CVD) processing chamber, or a physical vapor deposition (PVD) processing chamber.

In still other features, a showerhead for processing a substrate in a processing chamber comprises a first component, a second component, and a third component. The first component includes a disc-shaped portion and a cylindrical portion extending perpendicularly from the disc-shaped portion. The disc-shaped portion has a greater diameter than an outer diameter of the cylindrical portion. The cylindrical portion has an inner diameter greater than a diameter of the substrate. The disc-shaped portion includes first and second sets of holes having first and second diameters, respectively. The first and second sets of holes extend from a center of the disc-shaped portion to the inner diameter of the cylindrical portion. The second component is disc-shaped and includes first through holes aligned with the first set of holes in the first component. The second component has a top surface, side surfaces, and a bottom surface attached to the disc-shaped portion of the first component on a side opposite to the cylindrical portion and defining a plenum. The plenum is in fluid communication with the second set of holes in the first component and is separate from the first set of holes in the first component. The top surface of the second component includes a pair of arc-shaped grooves along a periphery and on opposite ends of the top surface and includes a plurality of grooves extending between the pair of arc-shaped grooves. The third component is disc-shaped and includes second through holes aligned with the first through holes in the second component and with the first set of holes in the first component. The third component has a bottom surface attached to the top surface of the second component. The first and second sets of holes are arranged in a hexagonal pattern, a triangular pattern, or a combination of a hexagonal pattern and a triangular pattern. Hexagons in the hexagonal pattern are equilateral hexagons, and triangles in the triangular pattern are equilateral triangles. The first set of holes are arranged in a hexagonal pattern, the second set of holes are lie on vertices of triangles within hexagons formed by the first set of holes, and one of the first set of holes lies within each of the triangles. The second set of holes are arranged in a hexagonal pattern, the first set of holes are lie on vertices of triangles within hexagons formed by the second set of holes, and one of the second set of holes lies within each of the triangles.

In other features, the third component further comprises a gas inlet in fluid communication with the plenum, a fluid inlet in fluid communication with a first one of the pair of arc-shaped grooves, and a fluid outlet in fluid communication with a second one of the pair of arc-shaped grooves.

In other features, the pair of arc-shaped grooves and the plurality of grooves are separate from the plenum and the first and second sets of holes, the pair of arc-shaped grooves surround the first through holes in the second component, or the pair of arc-shaped grooves and the plurality of grooves have equal depths.

In other features, the bottom surface of the second component further comprises a semicircular groove along a periphery of the bottom surface of the second component, the semicircular groove is in fluid communication with the plenum, and the semicircular groove surrounds the first through holes in the second component or the semicircular groove surrounds the pair of arc-shaped grooves.

In other features, the pair of arc-shaped grooves include a plurality of vertically extending ridges that contact the bottom surface of the third component, and a height of the plurality of vertically extending ridges is equal to a depth of the plurality of grooves.

In other features, the plurality of grooves are parallel to each other, or the plurality of grooves have a zig-zagged shape.

In other features, first ends of the plurality of grooves connect with a first one of the pair of arc-shaped grooves, and second ends of the plurality of grooves connect with a second one of the pair of arc-shaped grooves.

In other features, the first through holes in the second component lie between the plurality of grooves.

In other features, a ratio of a sum of cross-sectional area of the first set of holes to a cross-sectional area of the cylindrical portion of the first component is between 4.5% and 5.5%; a ratio of a sum of cross-sectional area of the first set of holes to a cross-sectional area of the cylindrical portion of the first component is between 4% and 6%; a ratio of a number of the first set of holes to a number of second set of holes is between 1.00 and 1.05; or a density of the first and second sets of holes is between 4 and 5 holes per square inch.

In still other features, a showerhead for processing a substrate in a processing chamber comprises a first component, a second component, and a third component. The first component includes a disc-shaped portion and a cylindrical portion extending perpendicularly from the disc-shaped portion. The disc-shaped portion has a greater diameter than an outer diameter of the cylindrical portion. The cylindrical portion has an inner diameter greater than a diameter of the substrate. The disc-shaped portion includes first and second sets of holes having first and second diameters, respectively. The first and second sets of holes extend from a center of the disc-shaped portion to the inner diameter of the cylindrical portion. The second component is disc-shaped and includes first through holes aligned with the first set of holes in the first component. The second component has a top surface, side surfaces, and a bottom surface attached to the disc-shaped portion of the first component on a side opposite to the cylindrical portion and defining a plenum. The plenum is in fluid communication with the second set of holes in the first component and is separate from the first set of holes in the first component. The top surface of the second component includes a pair of arc-shaped grooves along a periphery and on opposite ends of the top surface and includes a plurality of grooves extending between the pair of arc-shaped grooves. The third component is disc-shaped and includes second through holes aligned with the first through holes in the second component and with the first set of holes in the first component. The third component has a bottom surface attached to the top surface of the second component. The third component comprises an annular ridge on a top surface of the third component along a periphery of the third component and a recess extending from an inner diameter of the annular ridge to a center of the top surface of the third component.

In other features, the inner diameter of the annular ridge is greater than or equal to the inner diameter of the cylindrical portion of the first component, or an outer diameter of the annular ridge is greater than or equal to an outer diameter of the cylindrical portion of the first component.

In other features, a width of the annular ridge is greater than or equal to a thickness of the cylindrical portion of the first component, or the inner diameter of the annular ridge is greater than the diameter of the substrate.

In other features, a diameter of the recess is greater than or equal to the inner diameter of the cylindrical portion of the first component, or the recess has a greater diameter than the diameter of the substrate.

In other features, the second through holes in the third component lie within the inner diameter of the annular ridge, or the second through holes in the third component lie within the recess.

In still other features, a system comprises a processing chamber and a showerhead for processing a substrate in the processing chamber. The showerhead is arranged at a top end of the processing chamber. The showerhead comprises a first component, a second component, and a third component. The first component includes a disc-shaped portion and a cylindrical portion extending perpendicularly from the disc-shaped portion. The disc-shaped portion has a greater diameter than an outer diameter of the cylindrical portion. The cylindrical portion has an inner diameter greater than a diameter of the substrate. The disc-shaped portion includes first and second sets of holes having first and second diameters, respectively. The first and second sets of holes extend from a center of the disc-shaped portion to the inner diameter of the cylindrical portion. The second component is disc-shaped and includes first through holes aligned with the first set of holes in the first component. The second component has a top surface, side surfaces, and a bottom surface attached to the disc-shaped portion of the first component on a side opposite to the cylindrical portion and defining a plenum. The plenum is in fluid communication with the second set of holes in the first component and is separate from the first set of holes in the first component. The top surface of the second component includes a pair of arc-shaped grooves along a periphery and on opposite ends of the top surface and includes a plurality of grooves extending between the pair of arc-shaped grooves. The third component is disc-shaped and includes second through holes aligned with the first through holes in the second component and with the first set of holes in the first component. The third component has a bottom surface attached to the top surface of the second component. The system further comprises a plasma generator arranged above the third component of the showerhead to supply a plasma to the showerhead, a pedestal arranged in the processing chamber. The cylindrical portion of the first component of the showerhead surrounds a top portion of the pedestal. The system further comprises a gas delivery system to supply a gas to the plenum and a fluid delivery system to supply a fluid to one of the pair of arc-shaped grooves.

In other features, the first set of holes in the showerhead filters ions from the plasma and pass radicals from the plasma through the showerhead into the processing chamber.

In other features, a film deposited on the substrate has a non-uniformity of 0.0%, a film deposited on the substrate has a non-uniformity of less than 0.1%, or a gap between a bottom surface of the disc-shaped portion of the first component of the showerhead and a top surface of the pedestal is between 0.11 in. and 0.2 in.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system utilizing remote plasma and a showerhead according to the present disclosure;

FIG. 2 shows a side cross-sectional view of the showerhead of FIG. 1 according to the present disclosure;

FIG. 3 shows a perspective cross-sectional view of the showerhead of FIG. 1 according to the present disclosure;

FIG. 4 shows a bottom view of a plenum arranged in the showerhead of FIG. 1 for introducing a precursor gas into the showerhead according to the present disclosure;

FIG. 5 shows a top view of a cooling channel arranged in the showerhead of FIG. 1 for circulating a coolant in the showerhead according to the present disclosure;

FIG. 6 shows a bottom view of the showerhead of FIG. 1 showing an example of a hole pattern used in the showerhead according to the present disclosure;

FIG. 7 shows an expanded view of the hole pattern shown in FIG. 6;

FIG. 8 shows a top view of the showerhead of FIG. 1 according to the present disclosure;

FIG. 9 shows a perspective view of the top of the showerhead of FIG. 1 according to the present disclosure; and

FIG. 10 shows a perspective view of the bottom of the showerhead of FIG. 1 according to the present disclosure.

In the drawings, reference numbers may be reused to identify similar and/or identical elements.

### DETAILED DESCRIPTION

The present disclosure relates to substrate processing systems that use remote plasma with a grounded showerhead to filter damage-causing ions from the remote plasma and allow radicals in the remote plasma to pass into a processing chamber. The radicals, which have unpaired electrons but do not have a net charge like the ions, provide beneficial film properties. Holes in the showerhead that connect a source of remote plasma to the processing chamber are optimized to filter the ions and pass the radicals from the remote plasma. For convenience, these holes are called radical holes throughout the present disclosure.

In addition, one or more precursors are supplied to the processing chamber through a separate plenum in the showerhead that is optimized for dose uniformity and purge efficiency for ALD operation. The precursors are supplied from the separate plenum into the processing chamber through a second set of holes in the showerhead, which are called precursor holes throughout the present disclosure. Separating the delivery of radicals and precursors allows independent optimization of both to achieve optimal film properties and uniformity.

Characteristics such as diameter, aspect ratio, and quantity of the radical holes are selected to optimize the amount of radicals that are delivered to a substrate in the processing chamber while also balancing the effectiveness of filtering ions that can otherwise cause damage to the substrate. Further, a pattern (e.g., layout, distribution, and density) of the radical holes and the precursor holes is also optimized to provide film uniformity across the entire substrate. This architecture can be used with any type of plasma source and can also be used with remote plasma enhanced ALD or chemical vapor deposition (CVD) processes.

The showerhead includes a planar base portion and a cylindrical portion that extends perpendicularly downward from a periphery of the base portion. The base portion includes cooling and precursor plenums, the radical holes, and the precursor holes. The cylindrical portion has an outer wall and an inner wall. The inner wall of the cylindrical portion defines a bore of the showerhead. A pedestal that supports the substrate is arranged in the processing chamber directly below the base portion of the showerhead. The pedestal includes a planar top portion and a vertical base portion that extends perpendicularly downward from a center of the top portion. An inner diameter (ID) of the cylindrical portion of the showerhead (i.e., the diameter of the inner wall of the showerhead) is greater than an outer diameter (OD) of the top portion of the pedestal. The inner wall of the cylindrical portion of the showerhead surrounds and extends vertically below the top portion of the pedestal. The cylindrical portion of the showerhead shrouds the top portion of the pedestal. The pedestal is moved down to load the substrate, moved up to process the substrate, and moved down to remove the substrate. The top portion of the pedestal can be moved vertically up and down within the cylindrical portion of the showerhead to adjust a gap between the base portion and the top portion of the pedestal.

The cylindrical portion of the showerhead provides a relatively stable thermal and gas flow environment around an edge of the pedestal, which in turn simplifies the process of varying a gap between the showerhead and the pedestal. Specifically, the cylindrical portion of the showerhead, which extends vertically below the top portion of the pedestal, provides a symmetric thermal boundary condition (i.e., a region of relatively constant temperature) around the edge of the pedestal while the pedestal is moved vertically within the cylindrical portion of the showerhead to adjust the gap between the showerhead and the pedestal.

In addition, the cylindrical portion of the showerhead also provides a relatively constant constriction to gas flow around the edge of the pedestal while the pedestal is moved within the cylindrical portion of the showerhead, which simplifies the process of controlling a micro-volume of gases in the gap between the showerhead and the pedestal in ALD processes. A tunable gap between the showerhead and the pedestal allows precise control of the micro-volume in ALD processes. A narrow gap between the showerhead and the pedestal prevents depletion of radicals in the micro-volume in ALD processes. These and other features of the showerhead of the present disclosure are described below in detail.

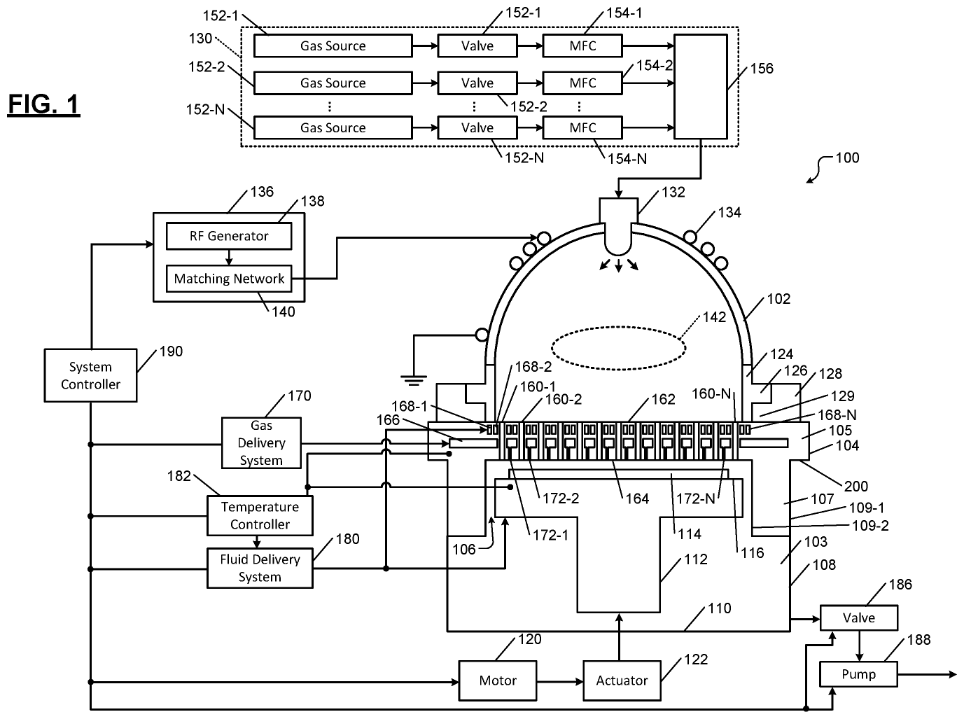

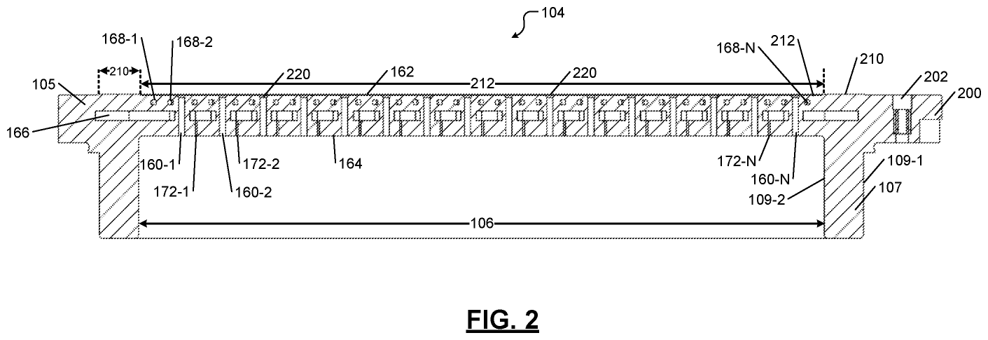

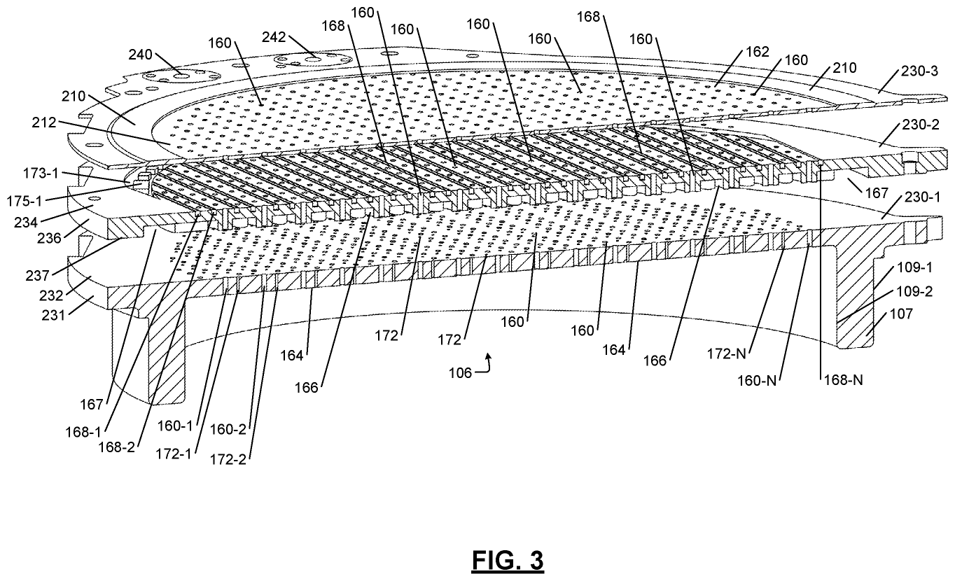

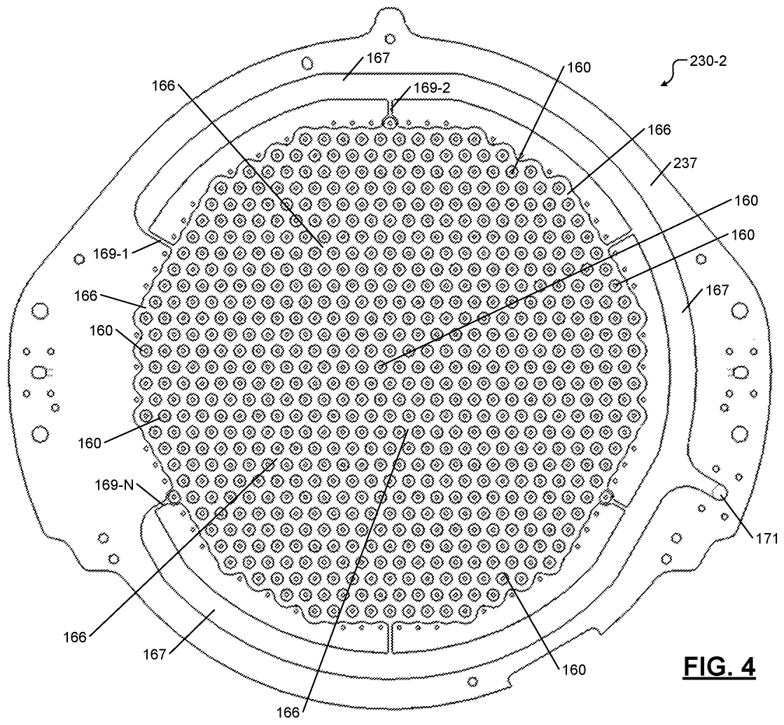

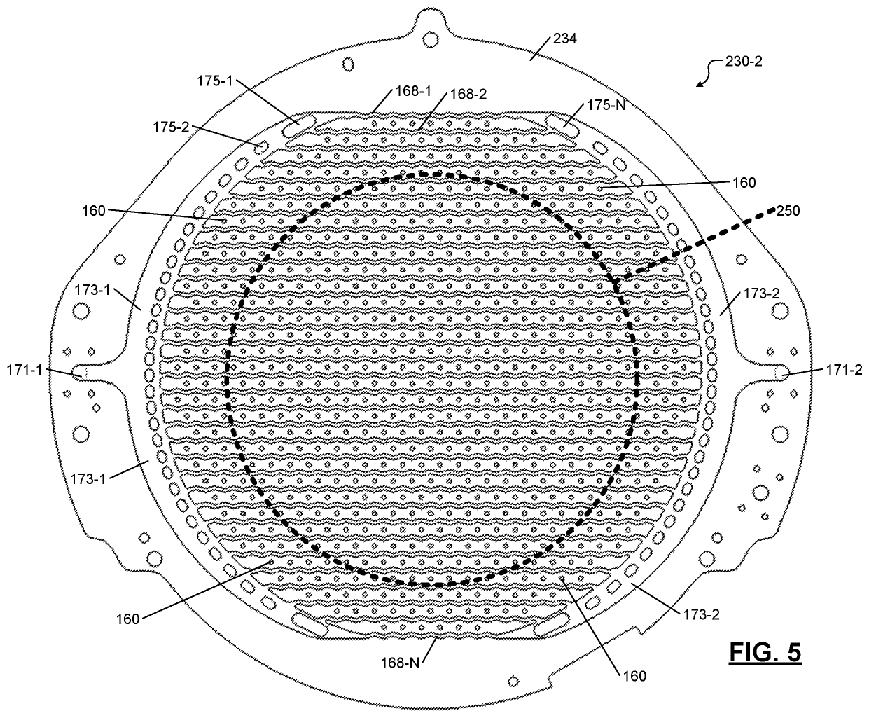

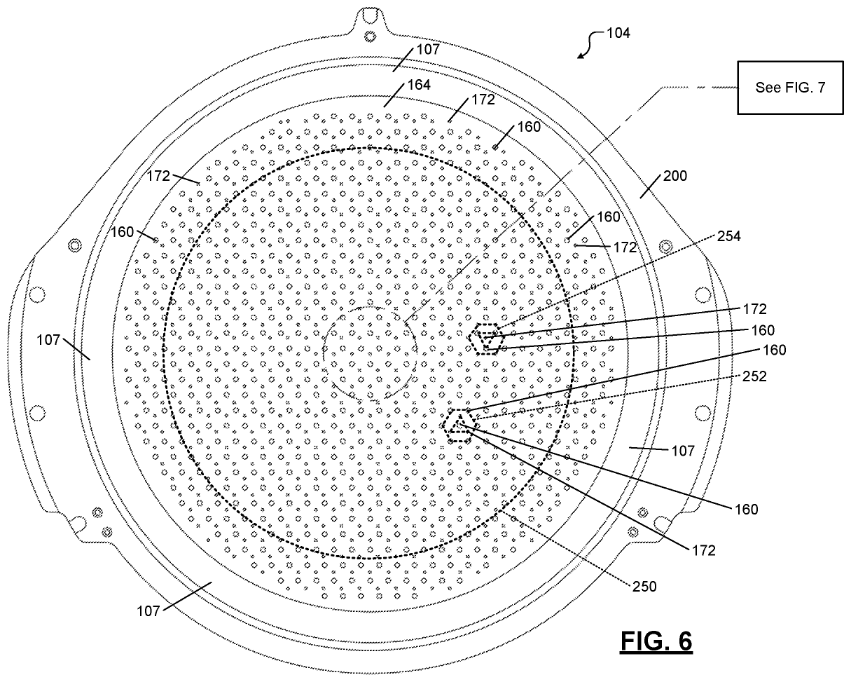

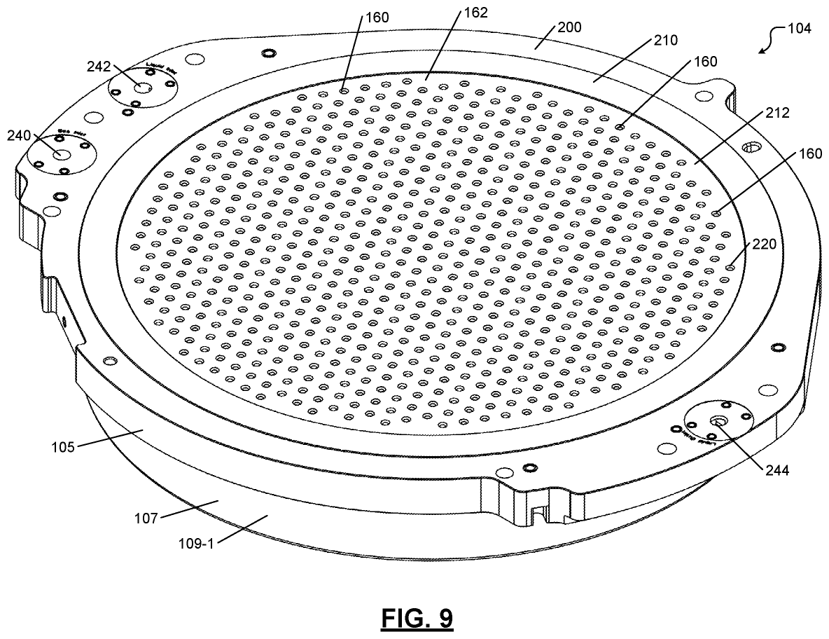

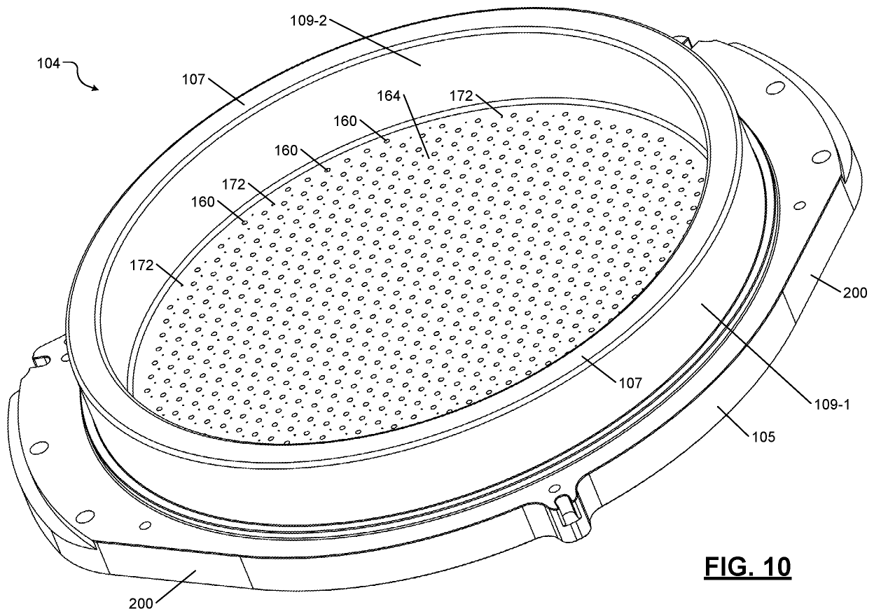

The present disclosure is organized as follows. An example of a substrate processing system utilizing remote plasma and the showerhead designed according to the present disclosure is shown and described with reference to FIG. 1. Side and perspective cross-sectional views of the showerhead are shown and described with reference to FIGS. 2 and 3. Bottom and top views of a gas plenum and a cooling channel in the showerhead are respectively shown and described with reference to FIGS. 4 and 5. Top and bottom views of the showerhead and various characteristics of the radical holes and the precursor holes are shown and described with reference to FIGS. 6-8. Perspective views of the top and bottom of the showerhead are respectively shown and described with reference to FIGS. 9 and 10.

FIG. 1 shows a substrate processing system 100 according to the present disclosure. The substrate processing system 100 comprises a processing chamber 103 and a showerhead 104. The showerhead 104 is made of a metal (e.g., aluminum) or an alloy. The showerhead 104 comprises a planar base portion 105 and a cylindrical portion 107 that extends perpendicularly downward from the base portion 105. The base portion 105 extends radially outward at the top of the cylindrical portion 107 forming a flange 200. The base portion 105 is described below in further detail with reference to FIGS. 2 and 3. The cylindrical portion 107 has an outer wall 109-1 and an inner wall 109-2. The inner wall 109-2 of the cylindrical portion 107 defines a bore 106 of the showerhead 104 (visible in FIG. 2). A diameter of the bore 106 is equal to a diameter of the inner wall 109-2 of the cylindrical portion 107 (i.e., an ID of the cylindrical portion 107) of the showerhead 104.

The processing chamber 103 has a sidewall 108 and a bottom wall 110. The sidewall 108 is attached to the bottom of the cylindrical portion 107 of the showerhead 104. The sidewall 108 is perpendicular to the base portion 105 of the showerhead 104 and extends vertically downward from the bottom of the outer wall 109-1 of the cylindrical portion 107 of the showerhead 104. The bottom wall 110 of the processing chamber 103 is parallel to the base portion 105 of the showerhead 104 and perpendicular to the sidewall 108 of the processing chamber 103 and is attached to the sidewall 108 of the processing chamber 103.

The substrate processing system 100 comprises a plasma source 102 arranged above the showerhead 104. The showerhead 104 is arranged between the plasma source 102 and the processing chamber 103. The showerhead 104 separates the plasma source 102 from the processing chamber 103. The plasma source 102 is described below in further detail.

A pedestal 112 is arranged in the processing chamber 103 directly below the showerhead 104. A substrate 114 is arranged on a top surface 116 of the pedestal 112 during processing. The top surface 116 of the pedestal 112 is planar and parallel to the base portion 105 of the showerhead 104 and parallel to the bottom wall 110 of the processing chamber 103. Accordingly, the substrate 114 is parallel to the top surface 116 of the pedestal 112, the base portion 105 of the showerhead 104, and the bottom wall 110 of the processing chamber 103. The ID of the cylindrical portion 107 of the showerhead 104 (i.e., the diameter of the inner wall 109-2 of the showerhead 104) is greater than an OD of the top surface 116 of the pedestal 112. The ID of the cylindrical portion 107 of the showerhead 104 (i.e., the diameter of the inner wall 109-2 of the showerhead 104) is also greater than an OD of the substrate 114.

An actuator 120 driven by a motor 122 can move the pedestal 112 vertically up and down relative to the showerhead 104 within the cylindrical portion 107 of the showerhead 104. The plasma source 102 and the showerhead 104 are fixed relative to the pedestal 112. A gap between a bottom of the base portion 105 of the showerhead 104 and the top surface 116 of the pedestal 112 may be adjusted by vertically moving the pedestal 112 within the cylindrical portion 107 of the showerhead 104. For example, the gap between the bottom of the base portion 105 of the showerhead 104 and the top surface 116 of the pedestal 112 may be of about 0.2 in., 0.15 in., or 0.11 in.

The plasma source 102 may be dome-shaped as shown or may be of any other shape. A bottom end of the plasma source 102 is open and is attached to a top end of a first cylindrical component 124. The first cylindrical component 124 has a first flange 126 that extends radially outwardly from about a center of the first cylindrical component 124. Accordingly, the first cylindrical component 124 has a shape of the letter “T” with the letter “T” rotated left by 90 degrees.

A second cylindrical component 128 surrounds the first cylindrical component 124. The second cylindrical component 128 has a second flange 129 that extends radially inwardly from a bottom end of the second cylindrical component 128. Accordingly, the second cylindrical component 128 has a shape of the letter “L” with the letter “L” flipped horizontally. The first flange 126 of the first cylindrical component 124 overhangs the second flange 129 of the second cylindrical component 128. The bottom ends of the first and second cylindrical components 124, 128 are attached to the top of the base portion 105 of showerhead 104 near the periphery of the base portion 105 of the showerhead 104.

For example only, the plasma source 102 generates a remote plasma (i.e., plasma outside the processing chamber 103) using ICP. The plasma source 102 receives one or more gases received from a gas distribution system 130 via a gas injector 132 arranged at the top of the plasma source 102 although gases may be injected into the plasma source 102 in other ways. A coil 134 is arranged around the plasma source 102. A first end of the coil 134 is grounded, and a second end of the coil 134 is connected to an RF generating system 136.

The RF generating system 136 generates and outputs RF power to the coil 134. For example only, the RF generating system 136 may include an RF generator 138 that generates the RF power. The RF power is fed by a matching network 140 to the coil 134. The RF power supplied to the coil 134 ignites the gas or gases injected by the gas injector 132 into the plasma source 102 and generates a plasma 142. Since the plasma source 102 generates the plasma 142 remotely from (i.e., outside) the processing chamber 103, the plasma 142 is called a remote plasma 142.

The gas delivery system 130 includes one or more gas sources 150-1, 150-2, . . . , and 150-N(collectively, the gas sources 150), where N is an integer greater than one. The gas sources 150 are connected by valves 152-1, 152-2, . . . , and 152-N (collectively, the valves 152) and mass flow controllers 154-1, 154-2, . . . , and 154-N (collectively, the mass flow controllers 154) to a manifold 156. The manifold 156 is connected to the gas injector 132.

The showerhead 104 is described below in further detail with reference to FIGS. 2-8. Briefly, the base portion 105 of the showerhead 104 comprises a first set of holes (also called radical holes as described above) 160-1, 160-2, . . . , and 160-N (collectively, the radical holes 160), where N is an integer greater than one. The radical holes 160 extend from a top surface 162 of the base portion 105 of the showerhead 104 to a substrate-facing bottom surface 164 of the base portion 105 of the showerhead 104 (also called a faceplate 164).

In addition, the base portion 105 of the showerhead 104 comprises a plenum 166 that is separate from and not in fluid communication with the radical holes 160. The plenum 166 receives one or more precursor gases from a second gas delivery system 170. The base portion 105 of the showerhead 104 further comprises a second set of holes (also called precursor holes as described above) 172-1, 172-2, . . . , and 172-N (collectively, the precursor holes 172), where N is an integer greater than one. The precursor holes 172 extend from the plenum 166 to the faceplate 164 of the showerhead 104. The radical holes 160 are not in fluid communication with the plenum 166 and the precursor holes 172. The radical holes 160 are greater in diameter and length than the precursor holes 172.

The base portion 105 of the showerhead 104 further comprises a plurality of grooves 168-1, 168-2, . . . , and 168-N(collectively, the grooves 168), where N is an integer greater than 1. The grooves 168 form a cooling channel (explained with reference to FIG. 3) through which a coolant flows. A fluid delivery system 180 supplies the coolant to the grooves 168 through an inlet (shown in FIG. 3) in the base portion 105 of the showerhead 104.

One or more temperature sensors (not shown) may be disposed in the base portion 105 of the showerhead 104. The temperature sensors may be connected to a temperature controller 182. The temperature controller 182 may control the supply of the coolant from the fluid delivery system 180 to the grooves 168 to control the temperature of the showerhead 104.

Further, while not shown, the pedestal 112 may include one or more heaters, a cooling system that receives a coolant from the fluid delivery system 180, and one or more temperature sensors. The temperature controller 182 may be connected to the temperature sensors in the pedestal 112. The temperature controller 182 may control power supply to the heaters. The temperature controller 182 may control the supply of the coolant from the fluid delivery system 180 to the cooling system in the pedestal 112 to control the temperature of the pedestal 112.

A valve 186 and pump 188 may control pressure in the processing chamber 103 and to evacuate reactants from the processing chamber 103 during processing. A system controller 190 may control the components of the substrate processing system 100 described above.

The showerhead 104 is now described in further detail. As described above, the showerhead 104 filters ions from the remote plasma 142 and passes radicals from the remote plasma 142 through the radical holes 160 into the processing chamber 103. The radicals react with the precursors in the gap between the showerhead 104 and the pedestal 112, and a thin film is deposited on the substrate 114 using a process such as ALD. The open area provided by the radical holes 160 for the radicals to pass through the showerhead 104, the density and pattern of the radical holes 160 and the precursor holes 172, and the structural and functional properties of the cylindrical portion 107 of the showerhead 104, all of which are described below in detail, provide near-zero radial and azimuthal non-uniformity in films deposited using the showerhead 104.

FIG. 2 shows a side cross-sectional view of the showerhead 104. The showerhead 104 includes the base portion 105 and the cylindrical portion 107 that extends vertically downwards from the base portion 105 of the showerhead 104. The base portion 105 of the showerhead 104 is horizontal and is parallel to the top surface 116 of the pedestal 112 (see FIG. 1) and to the bottom wall 110 of the processing chamber 103 (see FIG. 1). The base portion 105 extends radially outwardly from an outer diameter (OD) of the cylindrical portion 107 to form a flange 200. The flange 200 is fastened to a top plate (not shown) of the processing chamber 103 using a fastener 202. An O-ring (not shown) may be disposed between the flange 200 and the top plate to form a seal between the showerhead 104 and the top plate.

The top surface 162 of the base portion 105 of the showerhead 104 includes an annular ridge 210 having a relatively small height. The annular ridge 210 is also shown in FIGS. 3, 8, and 9. The annular ridge 210 protects the radical holes 160 during the handling of the showerhead 104 if the showerhead 104 is placed on a surface with the top surface 162 of the base portion 105 resting on the surface (i.e., if the showerhead 104 is placed face down on the surface). A width of the annular ridge 210 is approximately (but does not necessarily have to be) the same as the thickness of the cylindrical portion 107.

The top surface 162 of the base portion 105 of the showerhead 104 also includes a recess 212 that extends from an ID of the annular ridge 210 to the center of the showerhead 104. The recess 212 is also shown in FIG. 3. The diameter of the recess 212 is approximately (but does not necessarily have to be) the same as the ID of the cylindrical portion 107 of the showerhead 104. For example, the diameter of the recess 212 can be less than or equal to the ID of the cylindrical portion 107 of the showerhead 104. The radical holes 160 are arranged within the area of the recess 212. The recess 212 and the annular ridge 210 together protect the radical holes 160 during the handling of the showerhead 104.

The ID of the annular ridge 210 and the diameter of the recess 212 are approximately equal to the ID of the cylindrical portion 107. In some examples, the ID of the annular ridge 210 and the diameter of the recess 212 may be greater than the ID of the cylindrical portion 107. The OD of the annular ridge 210 may be greater than or equal to the OD of the cylindrical portion 107. In some examples, the ID of the annular ridge 210 and the diameter of the recess 212 may be less than the inner diameter of the cylindrical portion 107; and the OD of the annular ridge 210 may be less than the OD of the cylindrical portion 107. Accordingly, the width of the annular ridge 210 may be greater, equal, or less than the thickness of the cylindrical portion 107.

The base portion 105 of the showerhead includes the plenum 166 and the precursor holes 172 that extend vertically from the plenum 166 through the base portion 105 and through the faceplate 164 of the showerhead 104. The plenum 166 is shown and described in further detail with reference to FIGS. 3 and 4 below.

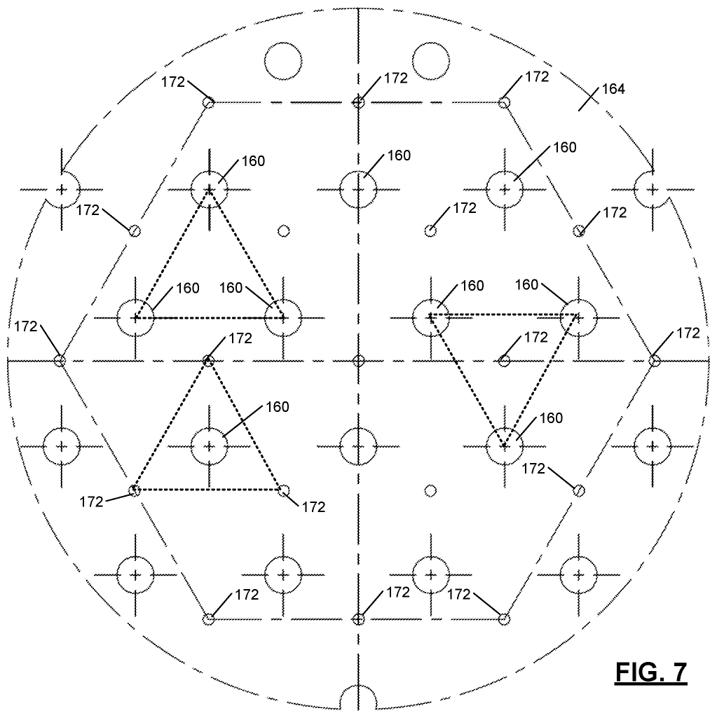

The radical holes 160 have a greater diameter and length than the precursor holes 172. The radical holes 160 are tapered at the top end (i.e., on the side facing the plasma source 102, see FIG. 1) as shown at 220. The radical holes 160 and the precursor holes 172 are cylindrical and are arranged in a pattern described below in detail with reference to FIGS. 6 and 7. As described in detail with reference to FIGS. 6 and 7, the total cross-sectional area of the radical holes 160 is optimized to filter ions from the remote plasma 142 and to pass only radicals from the remote plasma 142 through the showerhead 104 into the processing chamber 103.

The base portion 105 of the showerhead 104 includes the grooves 168 that form the cooling channel through which a coolant is circulated. The grooves 168 and the cooling channel are shown and described below in further detail with reference to FIGS. 3 and 5.

The outer wall 109-1 of the cylindrical portion 107 of the showerhead 104 does not directly contact the top plate of the processing chamber 103. Due to this feature and since the cylindrical portion 107 of the showerhead 104 extends vertically below the top surface 116 of the pedestal 112 on which the substrate 114 is arranged (see FIG. 1), the cylindrical portion 107 of the showerhead 104 provides a symmetric thermal boundary condition (i.e., a region of relatively constant temperature) around the edge of the top surface 116 of the pedestal 112 (see FIG. 1). Accordingly, the pedestal 112 can be moved vertically within (i.e., through the height of) the cylindrical portion 107 to adjust the gap between the showerhead 104 and the pedestal 112 without a significant change in the thermal boundary condition surrounding the edge of the top surface 116 of the pedestal 112, which is advantageous during substrate processing.

Further, as explained above, the cylindrical portion 107 of the showerhead 104 also provides a relatively constant constriction to gas flow around the edge of the top surface 116 of the pedestal 112 when the pedestal 112 is moved up or down within the cylindrical portion 107. This simplifies the process of controlling the micro-volume of gases in the gap between the showerhead 104 and the pedestal 112 since the gas flow conditions around the edge of the top surface 116 of the pedestal 112 remain relatively constant because the cylindrical portion 107 surrounds and is in close proximity to the edge of the top surface 116 of the pedestal 112. Accordingly, the pedestal 112 can be moved vertically within (i.e., through the height of) the cylindrical portion 107 to adjust the gap between the showerhead 104 and the pedestal 112 without a significant change in gas flow conditions around the edge of the top surface 116 of the pedestal 112.

A tunable gap between the faceplate 164 of the showerhead 104 and the top surface 116 of the pedestal 112 allows precise control of the micro-volume in ALD processes. Further, a narrow gap between the faceplate 164 of the showerhead 104 and the top surface 116 of the pedestal 112 prevents depletion of radicals in the micro-volume in the gap. Both these features can be provided because of the structure of the cylindrical portion 107 of the showerhead 104.

FIG. 3 shows a perspective cross-sectional view of the showerhead 104 and shows the structure of the showerhead 104 in further detail. The showerhead 104 comprises three components: a first component 230-1, a second component 230-2, and a third component 230-3. The first, second, and third components 230-1, 230-2, and 230-3 are diffusion bonded together (or joined together using fasteners or brazing) to form the showerhead 104.

The first component 230-1 includes a top portion 231 and the cylindrical portion 107 of the showerhead 104. The top portion 231 of the first component 230-1, second component 230-2, and the third component 230-3 form the base portion 105 of the showerhead 104. The top portion 231 of the first component 230-1 is planar and is disc-shaped. The cylindrical portion 107 extends perpendicularly downward from a periphery of the top portion 231. The top portion 231 of the first component 230-1 extends radially outwardly beyond the OD of the cylindrical portion 107. Accordingly, the diameter of the top portion 231 of the first component 230-1 is greater than the OD of the cylindrical portion 107. A region of the top portion 231 within the inner wall 109-2 of the cylindrical portion 107 (i.e., within the ID of the cylindrical portion 107) forms the faceplate 164 of the showerhead 104.

The radical holes 160 and the precursor holes 172 lie within a region of the faceplate 164 having a diameter that is less than or equal to the ID of the cylindrical portion 107. The diameter of the region in which the radical holes 160 and the precursor holes 172 lie is greater than the diameter of the substrate 114 and also greater than or equal to the OD of the top surface 116 the pedestal 112 as seen in FIGS. 1 and 6 (see a dotted circle 250 drawn in FIG. 6 indicating the diameter of the substrate 114). The region of the faceplate 164 in which the radical holes 160 and the precursor holes 172 lie has the same diameter and area as that of the recess 212, which is shown and described above with reference to FIG. 2.

In some examples, the first component 230-1 may be monolithic. That is, the top portion 231 of the first component 230-1 and the cylindrical portion 107 may not be separate components that are attached to each other; rather, the first component 230-1 may be a unitary structure, and the top portion 231 of the first component 230-1 may be integrated with the cylindrical portion 107 as a single monolithic structure. Alternatively, in some examples, the top portion 231 and the cylindrical portion 107 may be separate components that are joined together (e.g., by fasteners or diffusion bonding) to form the first component 230-1.

The second component 230-2 is now described with additional references made to FIGS. 4 and 5, which respectively show bottom and top views of the second component 230-2. The second component 230-2 is arranged on and is attached to a top surface 232 of the first component 230-1. The second component 230-2 is disc-shaped and has the same diameter as the top portion 231 of the first component 230-1. Accordingly, the diameter of the second component 230-2 is also greater than the OD of the cylindrical portion 107.

Top and side surfaces 234, 236 of the second component 230-2 and the top surface 232 of the first component 230-1 define the plenum 166. FIG. 4 shows the plenum 166 in further detail. As shown in FIG. 4, a bottom surface 237 of the second component 230-2 includes a semicircular or horse-shoe shaped groove 167 along a periphery of the bottom surface 237. The groove 167 is in fluid communication with the plenum 166 via a plurality of outlets 169-1, 169-2, . . . , and 169-N(collectively, the outlets 169), where N is an integer greater than 1. The groove 167 is in fluid communication with a gas inlet 240 provided on the third component 230-3 via an inlet 171, which is in fluid communication with a gas inlet 240. Accordingly, the plenum 166 is in fluid communication with the gas inlet 240 via the groove 167.

The gas inlet 240 is connected to the second gas delivery system 170 shown in FIG. 1. The plenum 166 receives one or more precursors from the second gas delivery system 170 via the gas inlet 240 and the groove 167. The plenum 166 is in fluid communication with the precursor holes 172 in the first component 230-1. The precursors flow from the gas inlet 240, through the groove 167, the plenum 166, and the precursor holes 172, into the processing chamber 103.

The radical holes 160 are drilled through the first, second, and third components 230-1, 230-2, and 230-3. Therefore, each of the first, second, and third components 230-1, 230-2, and 230-3 includes through holes that are portions of the radical holes 160. Since the radical holes 160 pass through the second component 230-2, the second component 230-2 includes through holes that are portions of the radical holes 160 (and are therefore also shown as 160) and that align with the portions of the radical holes 160 in the first component 230-1 and the third component 230-3.

The groove 167 surrounds but is not in fluid communication with the through holes 160 in the second component 230-2 that are portions of the radical holes 160. The through holes 160 in the second component 230-2 are not in fluid communication with the groove 167, the plenum 166, and the precursor holes 172. Accordingly, the radical holes 160 are not in fluid communication with the plenum 166 and the precursor holes 172.

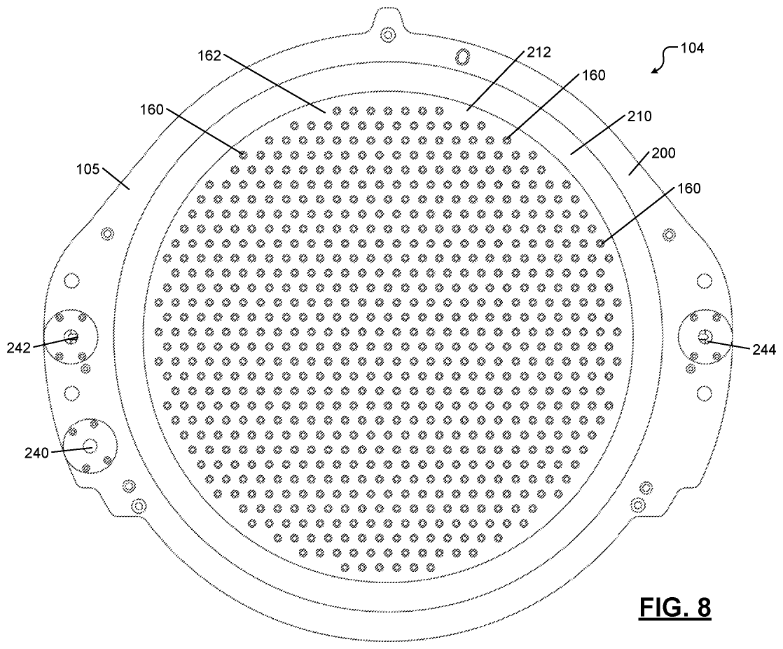

The top surface 234 of the second component 230-2 includes the grooves 168 that form the cooling channel. FIG. 5 shows the grooves 168 and the cooling channel in further detail. As shown in FIG. 5, the top surface 234 of the second component 230-2 includes two arc-shaped or semi-circular grooves 173-1 and 173-2 (collectively, the groves 173) along a periphery of the top surface 234. The grooves 173 are located on opposite sides of the top surface 234. The groove 173-1 includes an inlet 177-1 that is in fluid communication with a fluid inlet 242 provided on the third component 230-3. The groove 173-2 includes an outlet 177-2 that is in fluid communication with a fluid outlet 244 provided on the third component 230-3 (shown in FIGS. 8 and 9).

The grooves 168 are parallel to each other and extend across the top surface 234 between the grooves 173. Each of the grooves 168 has one end connected to the groove 173-1 and the other end connected to the groove 173-2. Accordingly, the grooves 168 are in fluid communication with the grooves 173. The grooves 173 and 168 form the cooling channel.

Since the grooves 173 are semi-circular, the grooves 168 are of varying lengths. The grooves 168 have the same width and depth. The grooves 168 are wavy or crooked (i.e., have a zig-zagged shape) but can also be straight instead. The grooves 173 are not directly connected to each other; rather, the grooves 173 are connected to each other by the grooves 168. The cooling channel formed by the grooves 173 and 168 extends beyond the diameter of the substrate 114 shown by the dotted circle 250.

The fluid inlet 242 provided on the third component 230-3 is connected to the fluid delivery system 180. The fluid delivery system 180 supplies the coolant to the fluid inlet 242. The coolant flows through the fluid inlet 242, through the groove 173-1, the grooves 168, and the groove 173-2, and exits through the fluid outlet 244.

The grooves 173 include a plurality of ridges 175-1, 175-2, . . . , and 175-N (collectively, the ridges 175), where N is an integer greater than 1. The ridges 175 are approximately oval in shape although the ridges 175 can be of any other shape. The ridges 175 extend vertically upwards from bottom portions of the grooves 173 and contact a bottom surface 238 of the third component 230-3. The number of the ridges 175 in each of the grooves 173 is (but does not need to be) approximately equal to the number of the grooves 168.

The ridges 175 help direct the flow of the coolant through the grooves 173, 168. The depth of the grooves 168 is approximately equal to the height of the ridges 173. The grooves 168 and 173 have the same depth. The groove 167 in the bottom surface 237 of the second component 230-2 surrounds the grooves 173 in the top surface 234 of the second component 230-2.

As shown in FIG. 5, the grooves 173 surround but are not in fluid communication with the through holes 160 in the second component 230-2 that are portions of the radical holes 160. The through holes 160 in the second component 230-2 that are portions of the radical holes 160 lie on either side of the grooves 168.

The third component 230-3 is arranged on and is attached to the top surface 234 of the second component 230-2. The third component 230-3 is also disc-shaped and also has the same diameter as the top portion 231 of the first component 230-1. Accordingly, the diameter of the third component 230-3 is also greater than the OD of the cylindrical portion 107. Further, the second and third components 230-2 and 230-3 have the same diameter.

The top surface 162 of the third component 230-3 includes the annular ridge 210 and the recess 212. The recess 212 extends from the ID of the annular ridge to the center of the top surface 162 of the third component 230-3. The annular ridge 210 and the recess 212 are already shown and described above in detail with reference to FIG. 2. Therefore, the annular ridge 210 and the recess 212 are not described again for brevity.

The third component 230-3 includes the gas inlet 240, the fluid inlet 242, and the fluid outlet 244 (shown in FIGS. 8 and 9). As explained above, the gas inlet 240 is in fluid communication with the groove 167 and the plenum 166 in the second component 230-2. The fluid inlet 242 is in fluid communication with the groove 173-1 in the second component 230-2. The fluid outlet 244 is in fluid communication with the groove 173-2 in the second component 230-2.

Accordingly, the fluid inlet 242 and the fluid outlet 244 are in fluid communication with the grooves 173 and 168 in the second component 230-2. The coolant supplied by the fluid delivery system 180 flows into the fluid inlet 242, through the cooling channel formed by the grooves 173, 168, and out of the cooling channel through the fluid outlet 244. The coolant that exits the fluid outlet 244 may be returned to the fluid delivery system 180.

As described above, the radical holes 160 are drilled through the first, second, and third components 230-1, 230-2, and 230-3; and therefore, each of the first, second, and third components 230-1, 230-2, and 230-3 includes through holes that are portions of the radical holes 160. Since the radical holes 160 pass through the third component 230-3, the third component 230-3 includes through holes that are portions of the radical holes 160 (and are therefore also shown as 160) and that align with the portions of the radical holes 160 in the second and first components 230-2, 230-1. The through holes 160 in the third component 230-3 are not in fluid communication with the plenum 166 and the grooves 167, 168, and 173 in the second component 230-2. Therefore, the through holes 160 in the third component 230-3 are not in fluid communication with the precursor holes 172.

The first, second, and third components 230-1, 230-2, and 230-3 are joined together by diffusion bonding. Diffusion bonding eliminates fillers typically used when brazing is used to join the components. Eliminating fillers eliminates possibility of contamination due to residual fillers that tend to persist after brazing and subsequent cleaning. Alternatively, fasteners and/or brazing may be used to join the first, second, and the third components 230-1, 230-2, and 230-3.

After the first, second, and third components 230-1, 230-2, and 230-3 are joined together (using any method), the radical holes 160 are drilled through the first, second, and the third components 230-1, 230-2, and 230-3 in the pattern described below with reference to FIGS. 6 and 7. The precursor holes 172 are drilled through the first component 230-1 in the pattern described below with reference to FIGS. 6 and 7. The precursor holes 172 in the first component 230-1 are aligned with the plenum 166 in the second component 230-2.

As described above, the radical holes 160 are cylindrical and have a greater diameter and length than the precursor holes 172. The radical holes 160 are tapered (conical) at the top end (i.e., the end facing the plasma source 102) as shown at 220. The radical holes 160 are not in fluid communication with the grooves 168, 173, and 167, the plenum 166, and the precursor holes 172. The pattern, layout, and the density of the radical holes 160 and the precursor holes 172 are now described in detail.

FIGS. 6 and 7 show the radical holes 160 and the precursor holes 172 in detail. FIG. 6 shows a bottom view of the showerhead 104. FIG. 7 shows an expanded view of a portion of the bottom view of the showerhead 104. As FIGS. 6 and 7 show, the radical holes 160 and the precursor holes 172 are arranged in a hexagonal/triangular pattern. This pattern is uniform about the center of the showerhead 104. While the hexagons and triangles are shown and described below as equilateral hexagons and triangles, other polygons and triangles may be used.

Specifically, the precursor holes 172 are arranged at vertices of equilateral hexagons as shown in FIG. 7. As shown at 252 in FIG. 6, the radical holes 160 are also arranged at vertices of equilateral hexagons. Further, as shown in FIG. 7, the precursor holes 172 are arranged at vertices of equilateral triangles. A radical hole 160 lies within the triangle formed by the precursor holes 172 at equal distances from the vertices of the triangle. The radical holes 160 are also arranged at vertices of equilateral triangles. In at least some triangles formed by the radical holes 160, a precursor hole 172 lies in the triangle formed by the radical holes 160. The precursor hole 172 lies at equal distances from the vertices of the triangle formed by the radical holes 160.

As shown at 252 in FIG. 6, the radical holes 160 are arranged at vertices of equilateral hexagons, and within a hexagon formed by the radical holes 160, the precursor holes 172 are arranged at vertices of a triangle, with a radical hole 160 arranged within the triangle. As shown at 254 in FIG. 6, the precursor holes 172 are arranged at vertices of equilateral hexagons, and within a hexagon formed by the precursor holes 172, the radical holes 160 are arranged at vertices of a triangle, with a precursor hole 172 arranged within the triangle.

The radical holes 160 and the precursor holes 172 are arranged in the above pattern relatively densely throughout the faceplate 164. For example, an average density of the radical holes 160 and the precursor holes 172 may be about 4.5 holes per square inch. For example, the average density may range between 4 to 5 holes per square inch.

Additionally, the number of radical holes 160 and the number of precursor holes 172 may be nearly equal. In some examples, the number of radical holes 160 may be slightly greater than the number of precursor holes 172. For example, a ratio of the number of radical holes 160 to the number of precursor holes 172 may be between 1.00 and 1.05.

Furthermore, the radical holes 160 and the precursor holes 172 are distributed in the above pattern and at the above density throughout the faceplate 164 (i.e., from the center to the ID of the cylindrical portion 107). FIG. 6 shows a circle 250 representing the diameter of the substrate 114. As shown, the pattern and the density of the radical holes 160 and the precursor holes 172 extend in the faceplate 164 radially beyond the circle 250 up to the ID of the cylindrical portion 107. The radial extension of the pattern and the density of the radical holes 160 and the precursor holes 172 beyond the OD of the substrate 114 ensures that the pattern and the density are uniform from the center of the faceplate 164 at least up to where the circle 250 (i.e., the OD of the substrate 114) extends on the faceplate 164.

Due to the extent and uniformity of these pattern and density features, materials can be uniformly deposited on the substrate 114. For example, a non-uniformity of 0.0%, less than 0.1%, less than 0.5%, or less than 1% can be achieved in material deposited on the substrate 114 using the plasma source 102 and the showerhead 104.

In addition, characteristics such as size (diameter and length) and the number of the radical holes 160 determine the efficiency with which the radicals from the remote plasma 142 can pass from the plasma source 102 through the showerhead 104 into the processing chamber 103. While some of these characteristics can be increased to increase the number of radicals that can pass through the radical holes 160, at some size or aspect ratio of the radical holes 160, the showerhead 104 cannot effectively filter the ions from the remote plasma 142. Therefore, the radical holes 160 are designed such that a percentage of area that is open for the radicals to pass from the plasma source 102 through the showerhead 104, while still filtering ions, is relatively high (examples follow).

Specifically, the percentage of the area that is open for the radicals to pass from the plasma source 102 through the showerhead 104 is defined as a ratio of a total cross-sectional area of all of the radical holes 160 to a cross-sectional area of the bottom of the plasma source 102 that is attached to the showerhead 104. The plasma source 102 and the showerhead 104 are designed such that the cross-sectional area of the bore 106 (i.e., the cross-sectional area of the inner wall 109-2 of the cylindrical portion 107) of the showerhead 104 is substantially the same as, and therefore can be substituted for, the cross-sectional area of the bottom of the plasma source 102.

Therefore, the percentage of the area that is open for the radicals to pass from the plasma source 102 through the showerhead 104 can be defined as a ratio of the total cross-sectional area of all of the radical holes 160 to the cross-sectional area of the bore 106 (i.e., the cross-sectional area of the inner wall 109-2 of the cylindrical portion 107) of the showerhead 104. Mathematically, this ratio is equal to the number of radical holes 160 multiplied by a square of the diameter of the radical holes 160 divided by a square of the ID of the bore 106 (i.e., the cross-sectional area of the inner wall 109-2 of the cylindrical portion 107) of the showerhead 104.

While this percentage of the area determines the efficiency with which the radicals can pass while filtering the ions from the remote plasma 142, the percentage of the area also improves the non-uniformity achieved by using the combination of the pattern and the density of the radical holes 160 and the precursor holes 172 described above. For example, to achieve near-zero non-uniformity (see examples above) in the material deposited on the substrate 114, in addition to the pattern and the density of the radical holes 160 and the precursor holes 172 described above, the percentage of the area that is open for the radicals to pass through the showerhead 104 may be about 5%. For example, the percentage of the area may be between 4.5% and 5.5%. For example, the percentage of the area may be between 4% and 6%.

Further, since optimizing the percentage of the area increases the efficiency with which the radicals can pass through the showerhead into the processing chamber 103, process cycles (e.g., ALD cycles) can be performed rapidly using the pattern, the density, and the percentage of the area designed as above. Since the process cycles can be performed rapidly, the rate at which substrates can be processed in a given amount of time (i.e., throughput) is increased.

FIG. 8 shows a top view of the showerhead 104. In this view, only the radical holes 160 are visible, and the precursor holes 172 are not visible. In addition, the gas inlet 240 that connects to the plenum 166 is shown. Further, the fluid inlet 242 and also the fluid outlet 244 that connect to the channel formed by the grooves 168 are shown. In addition, in this view, the tapering at the top of the radical holes 160 is shown at 220. The annular ridge 210 and the recess 212 are also shown. These and other elements seen in this view are already described above in detail with reference to FIGS. 2 and 3. Therefore, these elements are not described again for brevity.

FIGS. 9 and 10 respectively show perspective views of the top and bottom of the showerhead 104. Again, in the perspective view of the top of the showerhead 104 shown in FIG. 9, only the radical holes 160 are visible, and the precursor holes 172 are not visible. In addition, the gas inlet 240 that connects to the plenum 166 is shown. Further, the fluid inlet 242 and the fluid outlet 244 that connect to the channel formed by the grooves 168 are shown. This view provides a better perspective of the cylindrical portion 107 of the showerhead 104 than other drawings.

In the perspective view of the bottom of the showerhead 104 shown in FIG. 10, the radical holes 160 and the precursor holes 172 are shown as extending all the way to the ID of the cylindrical portion 107 of the showerhead 104 in the pattern described above with reference to FIGS. 7 and 8. In addition, the extent (or height) of the cylindrical portion 107 of the showerhead 104 relative to the base portion 105 of the showerhead 104 can be perceived from the bottom of the showerhead 104 in this view.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another are within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A showerhead for processing a substrate in a processing chamber, the showerhead comprising:
a first component including a disc-shaped portion and a cylindrical portion extending perpendicularly from the disc-shaped portion, the disc-shaped portion having a greater diameter than an outer diameter of the cylindrical portion, the cylindrical portion having an inner diameter greater than a diameter of the substrate, the disc-shaped portion including first and second sets of holes having first and second diameters, respectively, and the first and second sets of holes extending from a center of the disc-shaped portion to the inner diameter of the cylindrical portion;
a second component being disc-shaped, including first through holes aligned with the first set of holes in the first component, having a top surface, side surfaces, and a bottom surface attached to the disc-shaped portion of the first component on a side opposite to the cylindrical portion and defining a plenum that is in fluid communication with the second set of holes in the first component and that is separate from the first set of holes in the first component, the top surface including a pair of arc-shaped grooves along a periphery and on opposite ends of the top surface and including a plurality of grooves extending between the pair of arc-shaped grooves; and
a third component being disc-shaped, including second through holes aligned with the first through holes in the second component and with the first set of holes in the first component, and having a bottom surface attached to the top surface of the second component.

2. The showerhead of claim 1 wherein the first and second sets of holes are arranged in a hexagonal pattern, a triangular pattern, or a combination of a hexagonal pattern and a triangular pattern.

3. The showerhead of claim 2 wherein hexagons in the hexagonal pattern are equilateral hexagons and wherein triangles in the triangular pattern are equilateral triangles.

4. The showerhead of claim 1 wherein:
the first set of holes are arranged in a hexagonal pattern;
the second set of holes are lie on vertices of triangles within hexagons formed by the first set of holes; and
one of the first set of holes lies within each of the triangles;
or wherein:
the second set of holes are arranged in a hexagonal pattern;
the first set of holes are lie on vertices of triangles within hexagons formed by the second set of holes; and
one of the second set of holes lies within each of the triangles.

5. The showerhead of claim 1 wherein the third component further comprises:
a gas inlet in fluid communication with the plenum;
a fluid inlet in fluid communication with a first one of the pair of arc-shaped grooves; and
a fluid outlet in fluid communication with a second one of the pair of arc-shaped grooves.

6. The showerhead of claim 1 wherein:
the pair of arc-shaped grooves and the plurality of grooves are separate from the plenum and the first and second sets of holes;
the pair of arc-shaped grooves surround the first through holes in the second component; or
the pair of arc-shaped grooves and the plurality of grooves have equal depths.

7. The showerhead of claim 1 wherein the bottom surface of the second component further comprises a semicircular groove along a periphery of the bottom surface of the second component and wherein the semicircular groove is in fluid communication with the plenum and wherein the semicircular groove surrounds the first through holes in the second component or the semicircular groove surrounds the pair of arc-shaped grooves.

8. The showerhead of claim 1 wherein the pair of arc-shaped grooves include a plurality of vertically extending ridges that contact the bottom surface of the third component and wherein a height of the plurality of vertically extending ridges is equal to a depth of the plurality of grooves.

9. The showerhead of claim 1 wherein:
the plurality of grooves are parallel to each other; or
the plurality of grooves have a zig-zagged shape.

10. The showerhead of claim 1 wherein first ends of the plurality of grooves connect with a first one of the pair of arc-shaped grooves and wherein second ends of the plurality of grooves connect with a second one of the pair of arc-shaped grooves.

11. The showerhead of claim 1 wherein the first through holes in the second component lie between the plurality of grooves.

12. The showerhead of claim 1 wherein:
a ratio of a sum of cross-sectional area of the first set of holes to a cross-sectional area of the cylindrical portion of the first component is between 4.5% and 5.5%;
a ratio of a sum of cross-sectional area of the first set of holes to a cross-sectional area of the cylindrical portion of the first component is between 4% and 6%;
a ratio of a number of the first set of holes to a number of second set of holes is between 1.00 and 1.05; or
a density of the first and second sets of holes is between 4 and 5 holes per square inch.

13. A showerhead for processing a substrate in a processing chamber, the showerhead comprising:
a first component including a disc-shaped portion and a cylindrical portion extending perpendicularly from the disc-shaped portion, the disc-shaped portion having a greater diameter than an outer diameter of the cylindrical portion, the cylindrical portion having an inner diameter greater than a diameter of the substrate, the disc-shaped portion including first and second sets of holes having first and second diameters, respectively, and the first and second sets of holes extending from a center of the disc-shaped portion to the inner diameter of the cylindrical portion;
a second component being disc-shaped, including first through holes aligned with the first set of holes in the first component, having a top surface, side surfaces, and a bottom surface attached to the disc-shaped portion of the first component on a side opposite to the cylindrical portion and defining a plenum that is in fluid communication with the second set of holes in the first component and that is separate from the first set of holes in the first component, the top surface including a pair of arc-shaped grooves along a periphery and on opposite ends of the top surface and including a plurality of grooves extending between the pair of arc-shaped grooves; and
a third component being disc-shaped, including second through holes aligned with the first through holes in the second component and with the first set of holes in the first component, and having a bottom surface attached to the top surface of the second component, wherein the third component comprises:
an annular ridge on a top surface of the third component along a periphery of the third component; and
a recess extending from an inner diameter of the annular ridge to a center of the top surface of the third component.

14. The showerhead of claim 13 wherein:
the inner diameter of the annular ridge is greater than or equal to the inner diameter of the cylindrical portion of the first component; or
an outer diameter of the annular ridge is greater than or equal to an outer diameter of the cylindrical portion of the first component.

15. The showerhead of claim 13 wherein:
a width of the annular ridge is greater than or equal to a thickness of the cylindrical portion of the first component; or
the inner diameter of the annular ridge is greater than the diameter of the substrate.

16. The showerhead of claim 13 wherein:
a diameter of the recess is greater than or equal to the inner diameter of the cylindrical portion of the first component; or
the recess has a greater diameter than the diameter of the substrate.

17. The showerhead of claim 13 wherein:
the second through holes in the third component lie within the inner diameter of the annular ridge; or
the second through holes in the third component lie within the recess.

18. A system comprising:
a processing chamber;
a showerhead for processing a substrate in the processing chamber arranged at a top end of the processing chamber, the showerhead comprising:
a first component including a disc-shaped portion and a cylindrical portion extending perpendicularly from the disc-shaped portion, the disc-shaped portion having a greater diameter than an outer diameter of the cylindrical portion, the cylindrical portion having an inner diameter greater than a diameter of the substrate, the disc-shaped portion including first and second sets of holes having first and second diameters, respectively, and the first and second sets of holes extending from a center of the disc-shaped portion to the inner diameter of the cylindrical portion;
a second component being disc-shaped, including first through holes aligned with the first set of holes in the first component, having a top surface, side surfaces, and a bottom surface attached to the disc-shaped portion of the first component on a side opposite to the cylindrical portion and defining a plenum that is in fluid communication with the second set of holes in the first component and that is separate from the first set of holes in the first component, the top surface including a pair of arc-shaped grooves along a periphery and on opposite ends of the top surface and including a plurality of grooves extending between the pair of arc-shaped grooves; and
a third component being disc-shaped, including second through holes aligned with the first through holes in the second component and with the first set of holes in the first component, and having a bottom surface attached to the top surface of the second component;
the system further comprising:
a plasma generator arranged above the third component of the showerhead to supply a plasma to the showerhead;
a pedestal arranged in the processing chamber, wherein the cylindrical portion of the first component of the showerhead surrounds a top portion of the pedestal;
a gas delivery system to supply a gas to the plenum; and
a fluid delivery system to supply a fluid to one of the pair of arc-shaped grooves.

19. The system of claim 18 wherein the first set of holes in the showerhead filters ions from the plasma and pass radicals from the plasma through the showerhead into the processing chamber.

20. The system of claim 18 wherein:
a film deposited on the substrate has a non-uniformity of 0.0%;
a film deposited on the substrate has a non-uniformity of less than 0.1%; or
a gap between a bottom surface of the disc-shaped portion of the first component of the showerhead and a top surface of the pedestal is between 0.11 in. and 0.2 in.
